(19) United States
(12) Patent Application Publication
(10) Pub. No.: US 2016/0302303 A1
(43) Pub. Date: Oct. 13, 2016

(54) MOUNTING BOARD MODULE

(71) Applicant: SAMSUNG ELECTRO-MECHANICS CO., LTD., Suwon-si (KR)

(72) Inventors: Min Hoon KIM, Suwon-si (KR); Se Min JIN, Suwon-si (KR); Jae Hyun CHANG, Suwon-si (KR)

(73) Assignee: SAMSUNG ELECTRO-MECHANICS CO., LTD., Suwon-si (KR)

(21) Appl. No.: 15/075,732

(22) Filed: Mar. 21, 2016

(30) Foreign Application Priority Data
Apr. 8, 2015 (KR) 10-2015-0049615

(51) Int. Cl. H05K 1/02; H05K 1/18

(52) U.S. Cl. CPC H05K 1/0218; H05K 1/181; H05K 1/0243

(57) ABSTRACT

A mounting board module includes a board; a circuit unit disposed on a first side of the board; and a power supply unit disposed a second side of the board, opposite the first and configured to supply power to the circuit unit, wherein the board comprises a ground layer disposed between the circuit unit and the power supply unit, wherein the ground layer is configured to be electrically grounded.

### CROSS-REFERENCE TO RELATED APPLICATION

This application claims the benefit under 35 USC 119(a) of Korean Patent Application No. 10-2015-0049615, filed on Apr. 8, 2015 with the Korean Intellectual Property Office, the entire disclosure of which is incorporated herein by reference for all purposes.

### BACKGROUND

1. Field

The present disclosure relates to a mounting board module.

2. Description of Related Art

Recently, mounting board modules have continually been increased in capacity and decreased in size. In line with this, electronic elements mounted on mounting board modules have become highly integrated.

When an electronic element mounted on a mounting board module is operated, it may generate noise to negatively affect an electronic element adjacent thereto. Here, as electronic elements mounted on the mounting board module are highly integrated, a negative influence of the electronic elements may be increased. Also, as electronic elements become highly integrated, ground separation and a design for improving noise characteristics may not be easy due to size restrictions.

For example, in power semiconductor modules of household/industrial products, an electronic element, having sweep characteristics such as a power factor corrector, may generate noise when driven. The noise may negatively affect an adjacent electronic element, such as a LLC converter.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a mounting board module includes a board; a circuit unit disposed on a first side of the board; and a power supply unit disposed a second side of the board, opposite the first and configured to supply power to the circuit unit, wherein the board comprises a ground layer disposed between the circuit unit and the power supply unit, wherein the ground layer is configured to be electrically grounded.

The power supply unit may include a DC-DC converter and may supply a preset voltage to the circuit unit through a switching operation of the DC-DC converter. The mounting board module may further include a plurality of solder balls disposed on the other side of the board and surrounding the power supply unit.

In another general aspect, a mounting board module includes a board; a first circuit unit, disposed on a first surface of the board, configured to process a baseband signal; and a second circuit unit, disposed on a second side of the board, opposite the first surface, configured to process a switching signal, wherein the board includes a ground layer disposed between the first circuit unit and the second circuit unit, wherein the ground layer is an electrical a ground.

The second circuit unit is configured to process a signal switched by a DC-DC converter to output a preset voltage, and to supply the preset voltage to the first circuit unit.

Other features and aspects will be apparent from the following detailed description, the drawings, and the claims.

### BRIEF DESCRIPTION OF DRAWINGS

FIG. 1 is a cross-sectional view illustrating a mounting board module according to one or more embodiments;

FIG. 2 is a top view illustrating an upper surface of a mounting board module according to one or more embodiments;

FIG. 3 is a bottom view illustrating a lower surface of a mounting board module according to one or more embodiments;

FIG. 4 is a cross-sectional view illustrating a mounting board module according to one or more embodiments; and

FIG. 5 is a cross-sectional view illustrating a mounting board module according to one or more embodiments.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. Like numerals refer to like elements throughout. As used herein, the term “and/or” includes any and all combinations of one or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the exemplary embodiments.

Words describing relative spatial relationships, such as “below”, “beneath”, “under”, “lower”, “bottom”, “above”, “over”, “upper”, “top”, “left”, and “right”, may be used to conveniently describe spatial relationships of one device or elements with other devices or elements. Such words are to be interpreted as encompassing a device oriented as illustrated in the drawings, and in other orientations in use or operation. For example, an example in which a device includes a second layer disposed above a first layer based on the orientation of the device illustrated in the drawings also encompasses the device when the device is flipped upside down in use or operation.

The terminology used herein is for describing particular embodiments only and is not intended to be limiting of the present description. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

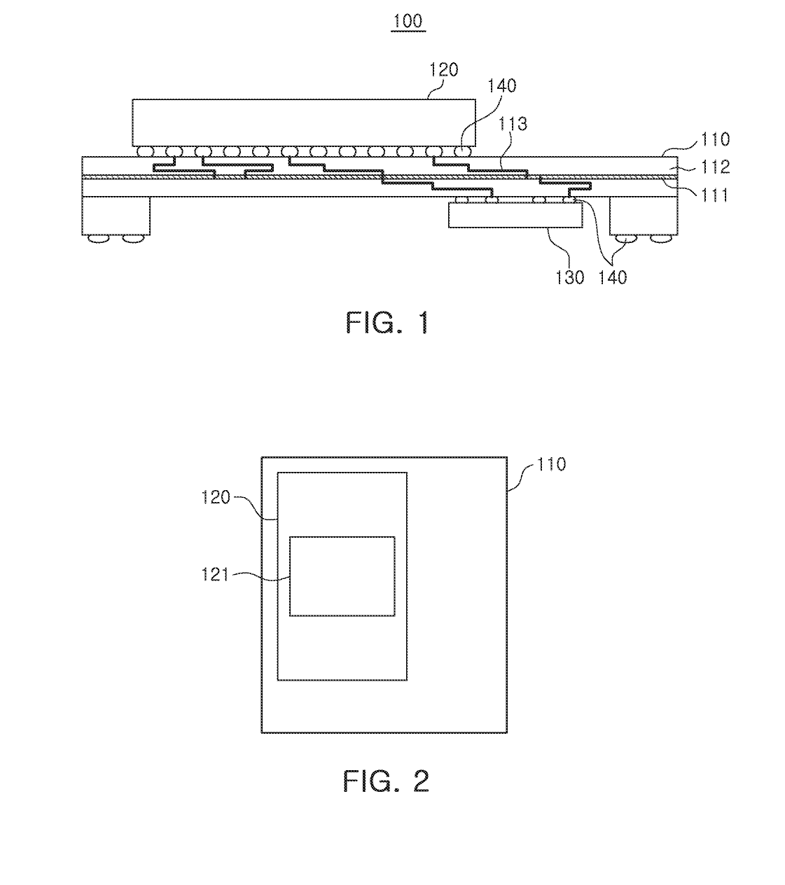

Referring to FIG. 1, the mounting board module 100 may include a board 110, a circuit unit 120, and a power supply unit 130. A mounting electrode may be formed on both sides of the board 110. Here, the upper and lower surfaces, or first and second, of the board 110 may be parallel to each other. The board 110 may be a ceramic board, a printed circuit board (PCB), or a flexible board, or any combination thereof.

The board 110 includes a ground layer 111, an insulating layer 112, and a plurality of conducting wires 113.

The ground layer 111 is an electrical ground GND. The ground layer 111 is parallel to the upper and lower surfaces of the board 110. Also, the ground layer 111 provides a ground voltage to the circuit unit 120 and the power supply unit 130. The ground layer 111 is interposed between the circuit unit 120 and the power supply unit 130 in order to block the circuit unit 120 from the power supply unit 130. Thus, a negative influence on the circuit unit 120 due to noise that is generated by the power supply unit 130 is reduced.

The insulating layer 112 is disposed between the upper or lower surface of the board 110 and the ground layer 111, and is formed of a material having higher magnetic permeability than that of air.

The plurality of conducting wires 113 disposed within the board 110 may be a metal having good conductivity such as copper (Cu), nickel (Ni), aluminum (Al), silver (Ag), or gold (Au), or any combination thereof. The plurality of conducting wires 113 electrically connect the circuit unit 120 or the power supply unit 130 to the ground layer 111.

The circuit unit 120 is mounted on one surface of the board 110 by means of the mounting electrode. The circuit unit 120 is described below with reference to FIG. 2.

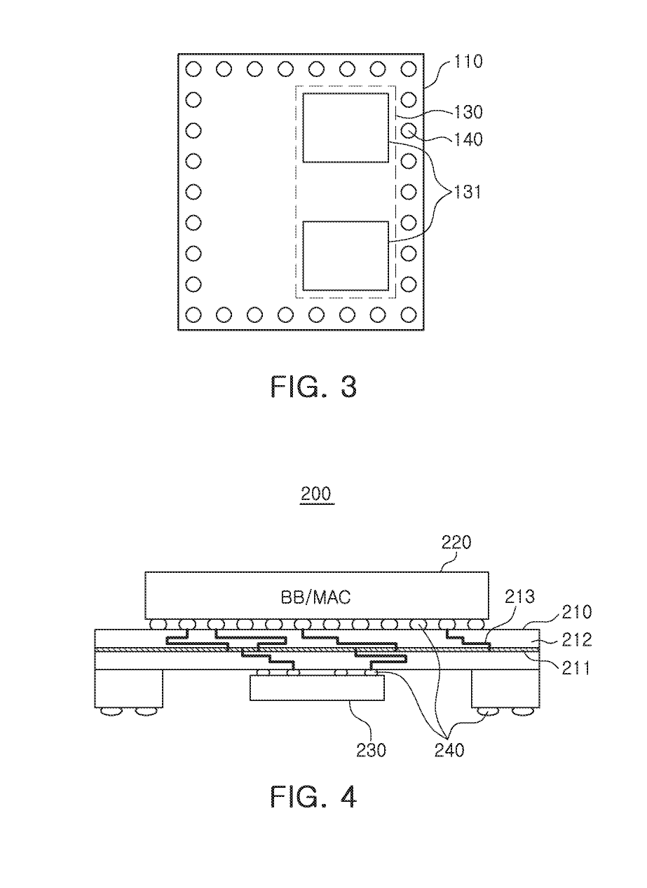

The power supply unit 130 is mounted on the other surface of the board 110 by means of the mounting electrode and supplies power to the circuit unit 120. That is, the power supply unit 130 is disposed on the lower side of the board 110 opposite the upper side of the board 110 where the circuit unit 120 is disposed. The board 110 acts as a boundary therebetween. Since the ground layer 111 cancels out noise generated by the power supply unit 130 or the circuit unit 120, noise characteristics of the power supply unit 130 and the circuit unit 120 are improved. The power supply unit 130 is described below with reference to FIG. 3.

The mounting board module 100 further includes a plurality of solder balls 140 disposed on the other side of the board 110 and surrounding the power supply unit 130. Here, the solder balls 140 bonds the power supply unit 130 and the circuit unit 120 to the board 110. Also, the solder balls 140 are connected to an electrode formed on the board 110 to serve as a pin or an external connection terminal of the module.

The solder balls 140 are disposed on the outside of the mounting board. Thus, either the circuit unit 120 or the power supply unit 130 may be mounted on the side on which the plurality of solder balls 140 are disposed. Here, a size, heating, durability, and a connection structure of the circuit unit 120 and the power supply unit 130 may be taken into consideration. For example, the power supply unit 130 may be mounted on the side on which the plurality of solder balls 140 are disposed. Since the plurality of solder balls 140 contribute to canceling out noise generated by the power supply unit 130, noise characteristics of the power supply unit 130 and the circuit unit 120 are further improved.

Referring to FIG. 2, the circuit unit 120 may include a radio frequency (RF) integrated circuit (IC) 121 processing an RF signal. For example, the RF signal may be used for communication based on the 802.11 ad standard. Here, the 802.11 ad standard is a next-generation high speed wireless communication standard using a frequency band of 60 GHz and supporting a data rate of 4.6 Gbps using 2 GHz BW.

For example, the circuit unit 120 may further include an IC processing a baseband signal, in addition to the RF IC 121. Here, the RF IC 121 and the IC processing a baseband signal are designed to be separated. In a case in which the circuit unit 120 supports communication based on the 802.11 ad standard, a data rate as high as 4.6 Gbps may be required. In this case, the ICs included in the circuit unit 120 may have a complicated structure. Thus, the circuit unit 120 may be designed to be separated from the power supply unit 130. For example, the circuit unit 120 is supplied with power through the power supply unit 130, rather than using an internal power supply means such as a power management unit (PMU).

Referring to FIG. 3, the power supply unit 130 includes a DC-DC converter 131. The DC-DC converter 131 is excellent in terms of power efficiency and heating. However, the power supply unit 130 may not necessarily provide power by means of the DC-DC converter 131. For example, the power supply unit 130 may supply power using an electronic element having sweep characteristics, such as a power factor corrector (PFC).

The DC-DC converter 131 supplies a preset voltage to the circuit unit 120 through a switching operation. Here, the switching operation refers to an operation of outputting a first voltage for a specific period of time and outputting a second voltage for the other remaining period of time based on a preset period. For example, in a case in which the first voltage is 1.8V and the second voltage is 0V, 1.8V is output during a half of the preset period and 0V is output during the other half of the preset period, whereby voltage of 0.9V may be output as an output voltage of the DC-DC converter 131. The switching operation of the DC-DC converter 131 generates switching noise. The switching noise is canceled out through the board 110 and the ground layer 111.

The power supply unit 130 outputs and supplies a plurality of output voltages to the circuit unit 120. For example, the power supply unit 130 include a plurality of DC-DC converters to supply a voltage of 1.8V and a voltage of 0.9V to the circuit unit 120. As the number of the DC-DC converters included in the power supply unit 130 is increased, switching noise generated by the power supply unit 130 increases, but the increased switching noise is canceled out through the board 110 and the ground layer 111. Thus, even if the circuit unit 120 of the mounting board module 100 is provided with a plurality of output voltages, a negative influence due to switching noise is reduced.

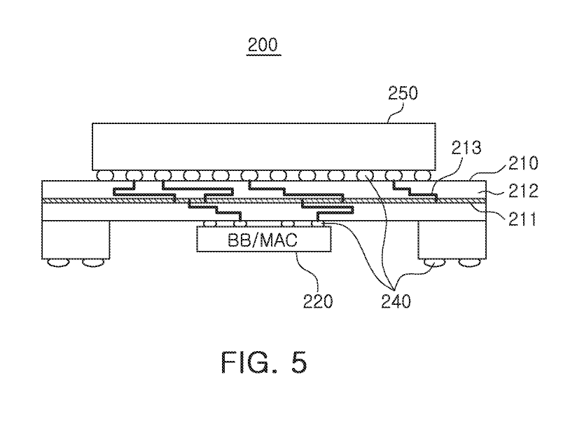

Hereinafter, a mounting board module 200 according to an embodiment will be described with reference to FIGS. 4 and 5. Redundant descriptions of the same components of the mounting board module 200 as those of the mounting board module 100 already described above with reference to FIGS. 1 through 3 will be omitted.

Referring to FIG. 4, the mounting board module 200 includes a board 210, a first circuit unit 220, a second circuit unit 230, and a plurality of solder balls 240.

A mounting electrode is formed on both sides of the board 210. For example, the board 210 includes a ground layer 211, an insulating layer 212, and a plurality of conducting wires 213. Since the ground layer 211 included in the board 210 cancels out noise generated by the first circuit unit 220 and the second circuit unit 230, noise characteristics of the first circuit unit 220 and the second circuit unit 230 is improved.

The first circuit unit 220 is mounted on an upper side of the board 210 and processes a baseband signal. For example, the first circuit unit 220 may be an IC supporting communication based on the 802.11 ad standard as described above.

The second circuit unit 230 is mounted on another side, or lower side, of the board 210, opposite the side the first circuit 220 is mounted, by means of the mounting electrode and processes a switching signal. For example, the second circuit unit 230 processes a signal switched by a DC-DC converter and output a preset voltage and supply the preset voltage to the first circuit unit 220. However, the second circuit unit 230 does not necessarily perform a power supply function by the DC-DC converter. That is, the second circuit unit 230 merely includes at least one circuit generating switching noise through a switching operation.

The plurality of solder balls 240 are also disposed on the lower side of the board 210 and surround the second circuit unit 230. For example, the second circuit unit 230 is mounted on the side on which the plurality of solder balls 240 are disposed, or the lower side of the board 210. Since the plurality of solder balls 240 contribute to canceling out noise generated by the second circuit unit 230, noise characteristics of the second circuit unit 230 and the first circuit unit 220 is further improved.

Referring to FIG. 5, the mounting board module 200 further include a third circuit unit 250.

The third circuit unit 250 mounted on one side of the board 210, for example the upper side, by means of a mounting board and processes an RF band signal. For example, the third circuit unit 250 and the first circuit unit 220 may be blocked by the ground layer 210 interposed therebetween. That is, the circuit processing an RF band signal and the circuit processing a baseband signal is separated by the ground layer 210 as a boundary therebetween, and accordingly, an influence of noise generated as the baseband signal is processed on the circuit processing the RF band signal is reduced.

As set forth above, the mounting board module according to one or more embodiments reduces a negative influence due to noise on an electronic element mounted thereon.

Also, the mounting board module according to one or more embodiments improves reception sensitive to noise, suppress a spurious phenomenon, and improve an error vector magnitude (EVM) regarding a high data rate.

As a non-exhaustive example only, a device as described herein may be a mobile device, such as a cellular phone, a smart phone, a wearable smart device (such as a ring, a watch, a pair of glasses, a bracelet, an ankle bracelet, a belt, a necklace, an earring, a headband, a helmet, or a device embedded in clothing), a portable personal computer (PC) (such as a laptop, a notebook, a subnotebook, a netbook, or an ultra-mobile PC (UMPC), a tablet PC (tablet), a phablet, a personal digital assistant (PDA), a digital camera, a portable game console, an MP3 player, a portable/personal multimedia player (PMP), a handheld e-book, a global positioning system (GPS) navigation device, or a sensor, or a stationary device, such as a desktop PC, a high-definition television (HDTV), a DVD player, a Blu-ray player, a set-top box, or a home appliance, or any other mobile or stationary device capable of wireless or network communication. In one example, a wearable device is a device that is designed to be mountable directly on the body of the user, such as a pair of glasses or a bracelet. In another example, a wearable device is any device that is mounted on the body of the user using an attaching device, such as a smart phone or a tablet attached to the arm of a user using an armband, or hung around the neck of the user using a lanyard.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A mounting board module comprising:
a board;
a circuit unit disposed on a first side of the board; and
a power supply unit disposed a second side of the board, opposite the first and configured to supply power to the circuit unit,
wherein the board comprises a ground layer disposed between the circuit unit and the power supply unit, wherein the ground layer is configured to be electrically grounded.

2. The mounting board module of claim 1, wherein the circuit unit comprises a radio frequency integrated circuit configured to process an RF signal.

3. The mounting board module of claim 1, wherein the power supply unit comprises a DC-DC converter and is configured to supply a preset voltage to the circuit unit through a switching operation of the DC-DC converter.

4. The mounting board module of claim 1, wherein the power supply unit is configured to output a plurality of output voltages and supply the plurality of output voltages to the circuit unit.

5. The mounting board module of claim 1, wherein the ground layer is electrically connected to the circuit unit and the power supply unit by a plurality of conducting wires, and interposed between the circuit unit and the power supply unit.

6. The mounting board module of claim 1, further comprising a plurality of solder balls disposed on the second side of the board and surrounding the power supply unit.

7. A mounting board module comprising:
a board;
a first circuit unit, disposed on a first surface of the board, configured to process a baseband signal; and
a second circuit unit, disposed on a second side of the board, opposite the first surface, configured to process a switching signal,
wherein the board includes a ground layer disposed between the first circuit unit and the second circuit unit, wherein the ground layer is configured to be electrically grounded.

8. The mounting board module of claim 7, further comprising a plurality of solder balls, disposed on the second side of the board, surrounding the second circuit unit,
wherein the second circuit unit is configured to process a signal switched by a DC-DC converter to output a preset voltage, and to supply the preset voltage to the first circuit unit.

9. A board module comprising:
a first circuit disposed on a first surface of a board;
a second circuit disposed on a second surface of the board, opposite the first surface; and
an electrically grounded layer, disposed in the board between the first circuit and the second circuit, configured to block noise from the first circuit from influencing the second circuit.

10. The board module of claim 9, wherein the first circuit comprises a radio frequency integrated circuit configured to process a baseband signal and the second circuit is a power supply unit.

11. The board module of claim 10, wherein the first circuit and the second circuit are electronically connected to electrically grounded layer through conducting wires interposed between the first surface and the second surface.

12. The board module of claim 9, wherein the board has a higher magnetic permeability than air.
